(19) United States
(12) Patent Application Publication
(10) Pub. No.: US 2025/0006831 A1
(43) Pub. Date: Jan. 2, 2025

(54) SEMICONDUCTOR DEVICE AND METHOD FOR FORMING THE SAME

(71) Applicant: Vanguard International Semiconductor Corporation, Hsinchu (TW)

(72) Inventors: Cheng-Wei CHOU, Taoyuan City (TW); Yung-Fong LIN, Taoyuan City (TW); Shin-Cheng LIN, Tainan City (TW); Hsiu-Ming WU, New Taipei City (TW)

(73) Assignee: Vanguard International Semiconductor Corporation, Hsinchu (TW)

(21) Appl. No.: 18/343,617

(22) Filed: Jun. 28, 2023

(51) Int. Cl. H01L 29/778; H01L 29/08; H01L 29/66

(52) U.S. Cl. CPC H01L 29/7786; H01L 29/0847; H01L 29/66431

(57) ABSTRACT

A semiconductor device and a method for forming the same are provided. The semiconductor device includes a substrate, a buffer layer on the substrate, a channel layer on the buffer layer, a barrier layer on the channel layer and a gate structure on the barrier layer. The gate structure includes a gate layer, a gate electrode layer, a first protection pattern layer and second protection spacers. The gate electrode layer covers the gate layer. The first protection pattern layer covers a first top surface of the gate electrode layer. The second protection spacers cover first side surfaces of the gate electrode layer, second side surfaces of the first protection pattern layer and a portion of the gate layer. First interfaces between the second protection spacers and the gate layer are coplanar with a second interface, which is between the gate electrode layer and the gate layer.

### BACKGROUND OF THE INVENTION

### Field of the Invention

The present invention relates to a semiconductor device and a method for forming the same, and, in particular, to a high electron mobility transistor device and a method for forming the same.

### Description of the Related Art

GaN-based semiconductor materials have many excellent material properties, such as high thermal resistance, a wide band-gap, high electron saturation rate, and better heat dissipation. GaN-based semiconductor materials are suitable for use in high-frequency and high-temperature operating environments. In recent years, GaN-based semiconductor materials have been used in fast charging devices, power supply modules for wireless communication base stations, electric vehicle-related components, and other high electron mobility transistors (HEMT) with heterogeneous interface structures.

High electron mobility transistors are also called heterostructure FETs (HFETs) or modulation-doped FETs (MODFETs), which include semiconductor materials with different energy gaps. A two-dimensional electron gas (2DEG) layer will be generated at the interface between adjacent different semiconductor materials. The high electron mobility transistor may be affected during the processes, resulting in poor electrical performance or poor uniformity. Therefore, developing a structure that may improve the performance and reliability of the high electron mobility transistor device is currently one of the most important research topics in the industry.

### BRIEF SUMMARY OF THE INVENTION

An embodiment of the present invention provides a semiconductor device. The semiconductor device includes a substrate, a buffer layer, a channel layer, a barrier layer and a gate structure. The buffer layer is located on the substrate. The channel layer is located on the buffer layer. The barrier layer is located on the channel layer. The gate structure is disposed on the barrier layer. The gate structure includes a gate layer, a gate electrode layer, a first protection pattern layer and second protection spacers. The gate electrode layer partially covers the gate layer. The first protection pattern layer completely covers the first top surface of the gate electrode layer. The second protection spacer covers first side surfaces of the gate electrode layer, second side surfaces of the first protection pattern layer and a portion of the gate layer not covered by the gate electrode layer, wherein first interfaces between the second protection spacers and the gate layer are coplanar with a second interface, which is between the gate electrode layer and the gate layer.

An embodiment of the present invention provides a method for forming a semiconductor device. The method for forming a semiconductor device includes providing a substrate. The method further includes sequentially forming a buffer layer, a channel layer, and a barrier layer on the substrate. The method further includes sequentially forming a gate material layer and a gate electrode material layer on the barrier layer. The method further includes forming a first protection material layer on the gate electrode material layer. The method further includes performing a patterning process to remove a portion of the first protection material layer and a portion of the gate electrode material layer until the top surface of the gate material layer is exposed, so as to form a first protection pattern layer and a gate electrode layer covering a portion of the gate material layer. The first protection pattern layer and the gate electrode layer. The method further includes entirely forming the second protection material layer. The method further includes removing the second protection material layer from the first protection pattern layer and from the gate material layer not covered by the first protection pattern layer, to form second protection spacers covering the gate electrode layer and side surfaces of the first protection pattern layer. The method further includes performing an etching process to remove the gate material layer not covered by the first protection pattern layer and the second protection spacers to form a gate layer. The method further includes directly forming a first interlayer dielectric layer on the first protection pattern layer and the second protection spacers.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure;

FIG. 2 is a schematic cross-sectional view of a semiconductor device in accordance with some embodiments of the disclosure;

FIGS. 3 to 10 are schematic cross-sectional views of intermediate stages of forming the semiconductor device of FIG. 1 in accordance with some embodiments of the disclosure e; and

FIGS. 11 and 12 are schematic cross-sectional views of intermediate stages of forming the semiconductor device of FIG. 2 in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

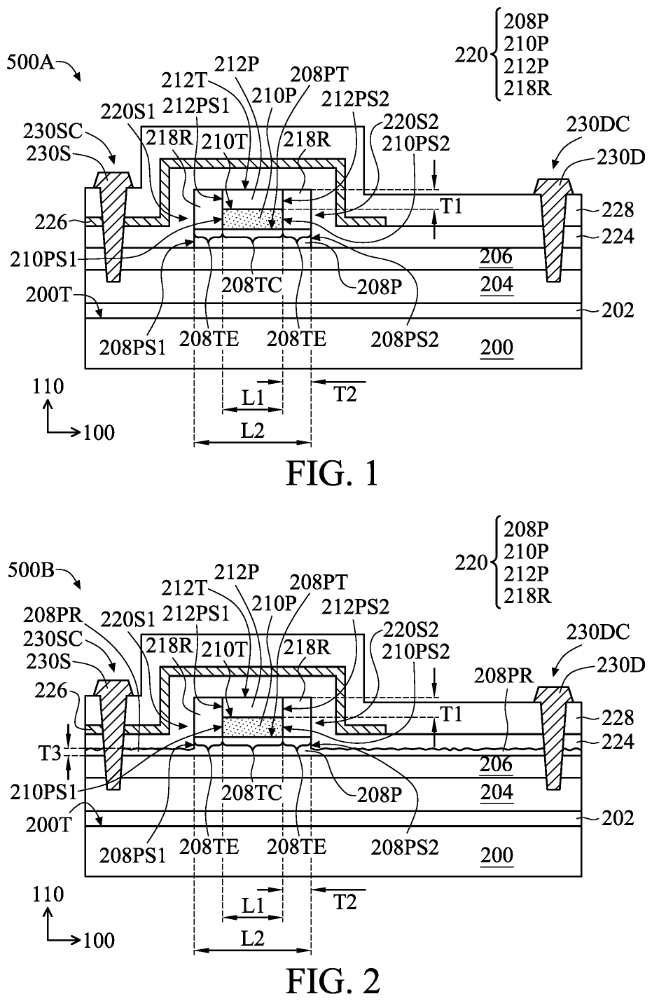

FIG. 1 is a schematic cross-sectional view of a semiconductor device 500A in accordance with some embodiments of the disclosure. In some embodiments, the semiconductor device 500A includes a high electron mobility transistor (HEMT). As shown in FIG. 1, a semiconductor device 500A includes a substrate 200, a buffer layer 202, a channel layer 204, a barrier layer 206 and a gate structure 220.

In some embodiments, the substrate 200 includes an elementary semiconductor including silicon (Si) or germanium (Ge); a compound semiconductor including gallium nitride (GaN), silicon carbide (SiC), gallium arsenide (GaAs), gallium phosphide (GaP), indium phosphide (InP), indium arsenide (InAs) and/or indium antimonide (InSb); an alloy semiconductor including SiGe, GaAsP, AlInAs, AlGaAs, GaInAs, GaInP, and/or GaInAs, or a combination thereof.

In some embodiments, the substrate 200 may be a semiconductor on insulator substrate, such as a silicon on insulator (SOI) substrate or a silicon germanium on insulator (SGOI) substrate. In other embodiments, the substrate 200 may be a ceramic substrate, such as an aluminum nitride (AlN) substrate, a silicon carbide (SiC) substrate, an aluminum oxide (Al2O3) substrate (or called a sapphire (sapphire) substrate), glass substrate, or other similar substrates. In some embodiments, the substrate 200 may include a ceramic substrate and a pair of blocking layers respectively disposed on upper and lower surfaces of the ceramic substrate. The ceramic substrate may include a ceramic material, and the ceramic material may include a metal-inorganic material. For example, the ceramic substrate may include silicon carbide (SiC), aluminum nitride (AlN), sapphire substrate, or other suitable materials. The sapphire substrate may be aluminum oxide. In some embodiments, the blocking layers located on the top and bottom surfaces of the ceramic substrate may include a single or multiple layers of insulating material and/or other suitable material layers, such as semiconductor layers. The insulating material layer may be oxide, nitride, oxynitride, or other suitable insulating materials. The semiconductor layer may be polysilicon. The blocking layer may be capable of preventing the diffusion of the ceramic substrate. The blocking layer may also prevent the ceramic substrate from interacting with other film layers or processing tools. In some embodiments, the blocking layer may also encapsulate the ceramic substrate. At this time, the barrier layer may not only cover the top and bottom surfaces of the ceramic substrate, but also cover both side surfaces of the ceramic substrate.

As shown in FIG. 1, the buffer layer 202 is located on the top surface 200T of the substrate 200. Since the crystal lattice and the coefficient of thermal expansion of the substrate 200 may be different from those of the features (such as the channel layer 204) above the substrate 200, strains may occur at or near the interface between the substrate 200 and the features above the substrate 200, resulting in defects such as cracks or warpage. Therefore, the buffer layer 202 on the substrate 200 can relief the strains in the features formed above the buffer layer 202 (e.g., the channel layer 204), preventing defects from forming in the above features. In some embodiments, the material of the buffer layer 202 may include III-V compound semiconductor materials, such as III-nitride. For example, the material of the buffer layer 102 may include: aluminum nitride (AlN), gallium nitride (GaN), aluminum gallium nitride (AlxGa1-xN, where 0<x<1), aluminum nitride Indium (AlInN), a combination of thereof, or other similar materials. In some embodiments, the buffer layer 202 may be formed by an epitaxial growth process, such as metal organic chemical vapor deposition (MOCVD), hydride vapor phase epitaxy (HVPE), molecular beam epitaxy (MBE), other suitable methods, or a combination of thereof. In some embodiments, the buffer layer 202 may be a multi-layer structure (not shown). For example, the buffer layer 202 may include a superlattice buffer layer and/or a gradient buffer layer. The superlattice buffer layer may be disposed on the substrate 200, and the gradient buffer layer is disposed on the superlattice buffer layer. The buffer layer 202 may effectively prevent dislocations in the substrate 200 from entering the features above the substrate 200. The buffer layer 202 may further improve the crystallization quality of other overlying films and/or layers.

In some embodiments, the semiconductor device 500A may optionally include a seed layer (not shown) between the substrate 200 and the buffer layer 202. The seed layer can relieve the lattice difference between the substrate 200 and the films and/or layers growing thereon, so as to improve the crystallization quality. In some embodiments, the material of the seed layer may include aluminum nitride (AlN), aluminum gallium nitride (AlGaN), other suitable materials, or a combination of thereof. In some embodiments, the seed layer of a single-layer or multi-layer structure may be formed by, for example, chemical vapor deposition (CVD), atomic layer deposition (ALD), physical vapor deposition (PVD), other suitable processes, or a combination of thereof.

The channel layer 204 is located on the buffer layer 202. In some embodiments, the material of the channel layer 104 includes a binary compound semiconductor of group III-V, such as group-III nitride. For example, the material of the channel layer 204 includes gallium nitride (GaN). In some embodiments, the channel layer 204 may be doped with n-type dopants or p-type dopants. In some embodiments, the channel layer 204 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

The barrier layer 206 is located on the channel layer 104. The material of the barrier layer 206 may include a ternary compound semiconductor of group III-V, such as group-III nitride. For example, the material of the barrier layer 206 may be aluminum gallium nitride (AlGaN), aluminum indium nitride (AlInN), or a combination thereof. In other embodiments, the barrier layer 206 may also include gallium nitride (GaN), aluminum nitride (AlN), gallium arsenide (GaAs), gallium indium phosphide (GaInP), aluminum gallium arsenide (AlGaAs), indium phosphide (InP), indium aluminum arsenide (InAlAs), indium gallium arsenide (InGaAs), other suitable III-V materials, or a combination of thereof. In some embodiments, the barrier layer 206 may be doped with n-type dopants or p-type dopants. In some embodiments, the barrier layer 206 may be formed by an epitaxial growth process, such as metal organic chemical vapor deposition (MOCVD), hydride vapor phase epitaxy (HVPE), molecular beam epitaxy (MBE), liquid phase epitaxy (LPE), other suitable processes, or a combination of thereof.

According to some embodiments of the disclosure, the channel layer 204 and the barrier layer 206 include different materials, and the interface between the channel layer 204 and the barrier layer 206 is a heterojunction structure. The lattice mismatch between the channel layer 204 and barrier layer 206 may result in stress that leads to piezoelectric polarization effect. In addition, the ionicity of the bonding between the group-III metals (such as aluminum (Al), gallium (Ga), or indium (In)) and nitrogen bonding is relatively strong, thereby resulting in spontaneous polarization. Due to the difference in energy gap between the heterogeneous materials of the channel layer 204 and the barrier layer 206 and the aforementioned piezoelectric polarization and spontaneous polarization effects, two-dimensional electron gas (2DEG) (not shown) is formed at the heterogeneous interface between the channel layer 204 and the barrier layer 206. In some embodiments, the two-dimensional electron gas is used as the conductive carriers of the semiconductor device 500A.

The gate structure 220 is disposed on the barrier layer 206 and covers a portion of the barrier layer 206. In some embodiments, the gate structure 220 includes a gate layer 208P, a gate electrode layer 210P, a first protection pattern layer 212P, and second protection spacers 218R.

The gate layer 208P is located on a portion of the barrier layer 206 and is in contact with the barrier layer 206. As shown in FIG. 1, the gate layer 208P may have a rectangular cross-section as shown in FIG. 1. In some embodiments, the gate layer 208P has a top surface 208 PT and side surfaces 208PS1, 208PS2 opposite to each other. The side surfaces 208PS1 and 208PS2 of the gate layer 208P are connected to the top surface 208 PT and the barrier layer 206 of the gate layer 208P. In addition, each of the side surfaces 208PS1 and 208PS2 of the gate layer 208P may be a planar surface extending from the top surface 208PT of the gate layer 208P to the barrier layer 206 along the direction 110 (the direction substantially perpendicular to the top surface 200T of the substrate 200, and substantially perpendicular to the direction 100, which can also be regarded as the vertical direction). In some embodiments, the material of the gate layer 208P may include p-type doped III-V semiconductors, such as gallium nitride (GaN), aluminum gallium nitride (AlGaN), aluminum nitride (AlN), arsenic Gallium (GaAs), aluminum gallium arsenide (AlGaAs), indium phosphide (InP), aluminum indium arsenide (InAlAs), indium gallium arsenide (InGaAs), or other III-V semiconductors. In other embodiments, the gate layer 208P includes p-type doped II-VI semiconductors, such as cadmium sulfide (CdS), cadmium telluride (CdTe), zinc sulfide (ZnS), or other II-VI semiconductors. In this embodiment, the gate layer 208P is p-type doped GaN (for example, the gate layer 208P may be composed of multiple p-type doped GaN thin layers with different dopant concentrations). In some embodiments, the gate layer 208P is formed by metal organic chemical vapor deposition (MOCVD), hydride vapor phase epitaxy (HVPE), molecular beam epitaxy (MBE), a combination of thereof, or other suitable methods and subsequent patterning process. In some embodiments, the gate layer 208P may be doped with dopants. For example, the dopants may include magnesium (Mg), zinc (Zn), calcium (Ca), beryllium (Be), strontium (Sr), barium (Ba), radium (Ra), carbon (C), silver (Ag), gold (Au), lithium (Li) or sodium (Na), so that the conductivity type of the gate layer 208P is p-type.

The gate electrode layer 210P is located on the gate layer 208P. The gate electrode layer 210P is in contact with and partially covers the top surface 208PT of the gate layer 208P, so that an interface 208TC between the gate electrode layer 210P and the gate layer 208P is located at the central portion of the top surface 208PT of the gate layer 208P. As shown in FIG. 1, the gate electrode layer 210P may have a top surface 210T and side surfaces 210PS1 and 210PS2 connected to the top surface 210T and opposite to each other. In some embodiments, a lateral length L1 of the gate electrode layer 210P is less than a lateral length L2 of the gate layer 208P. As shown in FIG. 1, the side surfaces 210PS1, 210PS2 of the gate electrode layer 210P are recessed from the side surfaces 208PS1, 208PS2 of the gate layer 208P, so that a peripheral portion of the top surface 208PT of the gate layer 208P is exposed from the gate electrode layer 210P. In other words, the side surfaces 210PS1, 210PS2 of the gate electrode layer 210P are located directly above the top surface 208PT of the gate layer 208P.

In some embodiments, the material of the gate electrode layer 210P may include metal, metal nitride, metal oxide, metal alloy, other suitable conductive materials, or a single-layer or multi-layer structure formed by a combination of thereof, or a combination of thereof. The metals may include, for example, gold (Au), nickel (Ni), platinum (Pt), palladium (Pd), iridium (Ir), titanium (Ti), chromium (Cr), tungsten (W), aluminum (Al), copper (Cu), similar materials, an alloy thereof, or a combination thereof. The metal alloy may include titanium tungsten (TiW). The metal nitrides may include molybdenum nitride (MoN), tungsten nitride (WN), titanium nitride (TiN), tantalum nitride (TaN), tantalum silicon nitride (TaSiN), tantalum carbide nitride (TaCN), nitrogen aluminum titanium (TiAlN), or other similar materials. In other embodiments, the conductive material of the gate electrode layer 210P may include nickel silicide (NiSi), cobalt silicide (CoSi), tantalum carbide (TaC), titanium aluminide (TiAl), or other similar materials. In this embodiment, the gate electrode layer 210P is titanium nitride (TiN).

In some embodiments, the gate electrode layer 210P may be formed by a deposition process followed by a patterning process. For example, the deposition process may include chemical vapor deposition (CVD), atomic layer deposition (ALD), or physical vapor deposition (PVD) such as sputtering or evaporation.

The first protection pattern layer 212P is located on the gate electrode layer 210P. The first protection pattern layer 212P is in contact with and completely covers the top surface 210T of the gate electrode layer 210P. As shown in FIG. 1, the first protection pattern layer 212P may have a top surface 212T and side surfaces 212PS1 and 212PS2 connected to the top surface 212T and opposite to each other. In some embodiments, the side surfaces 210PS1, 210PS2 of the gate electrode layer 210P are aligned with the corresponding side surfaces 212PS1, 212PS2 of the first protection pattern layer 212P in a direction substantially parallel to the direction 110. In other words, the side surfaces 212PS1, 212PS2 of the first protection pattern layer 212P overlap the corresponding side surfaces 210PS1, 210PS2 of the gate electrode layer 210P in a direction substantially parallel to the direction 110, and are located directly above the top surface 208PT of the gate layer 208P. In some embodiments, the material of the first protection pattern layer 212P may include a dielectric material, such as silicon oxide (SiO2), silicon carbide, silicon nitride, silicon oxynitride, silicon carbonitride, silicon oxycarbide, silicon oxycarbonitride, tetraethoxysilane (TEOS) oxide, low dielectric constant dielectric material (the dielectric constant is less than 4), aluminum oxide, aluminum nitride, other suitable materials or a combination of thereof. In this embodiment, the first protection pattern layer 212P is silicon oxide (SiO2).

In some embodiments, the first protection pattern layer 212P may be formed through a deposition process followed by a patterning process. For example, deposition processes may include chemical vapor deposition (CVD), physical vapor deposition (PVD), atomic layer deposition (ALD), high-density plasma chemical vapor deposition (HDPCVD), metal organic chemical Vapor deposition (MOCVD), remote plasma chemical Vapor deposition (RPCVD), plasma enhanced chemical vapor deposition (PECVD), electroplating, other suitable processes, or a combination of thereof. In some embodiments, a thickness T1 of the first protection pattern layer 212P may be in the range of 1 nm to 100 nm, for example, 40 nm.

The second protection spacer 218R covers and is in contact with the entire side surfaces 210PS1, 210PS2 of the gate electrode layer 210P and the side surfaces 212PS1, 212PS2 of the first protection pattern layer 212P. Moreover, the second protection spacer 218R covers and is in contact with a portion of the top surface 208PT of the gate layer 208P not covered by the gate electrode layer 210P, so that the entire side surfaces 208PS1 and 208PS2 of the gate layer 208P are exposed from the second protection spacer 218R. An interface 208TE between the second protection spacer 218R and the gate layer 208P is located the peripheral portion of the top surface 208PT of the gate layer 208P (close to the side surfaces 208PS1, 208PS2 of the gate layer 208P). In some embodiments, each interface 208TE is a planar substrate. In some embodiments, the gate electrode layer 210P and the second protection spacer 218R are in contact with different portions of the top surface 208PT of the gate layer 208P (e.g., a central portion and a peripheral portion of the top surface 208PT). The interface 208TE between the second protection spacer 218R and the gate layer 208P is adjacent to the interface 208TC between the gate electrode layer 210P and the gate layer 208P. Also, in some embodiments, the interface 208TE between the second protection spacer 218R and the gate layer 208P and the interface 208TC between the gate electrode layer 210P and the gate layer 208P are coplanar.

In some embodiments, the first protection pattern layer 212P and the second protection spacer 218R may include the same or similar materials. In this embodiment, both the first protection pattern layer 212P and the second protection spacer 218R are silicon oxide (SiO2). In some embodiments, the second protection spacer 218R may be formed on the side surfaces 210PS1 and 210PS2 of the gate electrode layer 210P and the side surfaces 212PS1 and 212PS2 of the first protection pattern layer 212P in a self-aligned manner by a deposition process (the same or similar to the deposition process for forming the first protection pattern layer 212P) and a subsequent anisotropic etching process. In this embodiment, the deposition process used to form the first protection pattern layer 212P and the second protection spacer 218R may be plasma enhanced chemical vapor deposition (PECVD) with a relatively low process temperature (about 200-450° C.). In some embodiments, the lateral length L1 of the first protection pattern layer 212P in the direction 100 (a direction substantially parallel to the top surface 200T of the substrate 200, which can also be regarded as a lateral direction) and the thickness T2 of the second protection spacer 218R determine the lateral length L2 of the gate layer 208P in the direction 100 (substantially parallel to the top surface 200T of the substrate 200, which can also be regarded as a lateral direction) (that is, the sum of the lateral length L1 and twice the thickness T2 is equal to the lateral length L2). In some embodiments, the thickness T2 of the second protection spacer 218R in the direction 100 may be greater than or equal to the thickness T1 of the first protection pattern layer 212P in the direction 110. For example, the thickness T2 of the second protection spacer 218R along the direction 100 may be in a range of 20 nm to 150 nm, such as 70 nm.

As shown in FIG. 1, the semiconductor device 500A further includes an interlayer dielectric layer 224 disposed on the barrier layer 206. Moreover, the interlayer dielectric layer 224 completely covers the gate structure 220. The interlayer dielectric layer 224 is in contact with the first protection pattern layer 212P and the second protection spacer 218R, the side surfaces 208PS1, 208PS2 of the gate layer 208P and the barrier layer 206 not covered by the gate structure 220. Moreover, the interlayer dielectric layer 224 is separated from the gate electrode layer 210P by the first protection pattern layer 212P and the second protection spacer 218R. In some embodiments, the interlayer dielectric layer 224 may include dielectric materials such as silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glasses (OSG), low-k dielectric materials, and/or other suitable dielectric materials, or a combination of thereof. The low-k dielectric materials may include (but not limited to) fluorinated silica glass (FSG), hydrogen silsesquioxane (HSQ), carbon-doped silicon oxide, amorphous fluorinated carbon, parylene, bis-benzocyclobutene (BCB), polyimide, or a combination thereof. In some embodiments, the interlayer dielectric layer 224 may be formed by a deposition process. For example, the deposition process may include spin-on coating, chemical vapor deposition (CVD), atomic layer deposition (ALD), low-pressure chemical vapor deposition (LPCVD), high-density plasma chemical vapor deposition (HDPCVD), other suitable processes, or a combination of thereof. In this embodiment, the deposition process for forming the interlayer dielectric layer 224 may be a low pressure chemical vapor deposition (LPCVD) with a relatively high process temperature (about 600-1000° C.).

As shown in FIG. 1, the semiconductor device 500A further includes a conductive pattern 226 disposed on a portion of the interlayer dielectric layer 224. Moreover, the conductive pattern 226 completely covers the gate structure 220. In some embodiments, the conductive pattern 226 may serve as a field plate structure, which may be used to disperse the electric field of the gate structure 220. In some embodiments, the conductive pattern 226 and the gate electrode layer 210P may include the same or similar materials and processes.

As shown in FIG. 1, the semiconductor device 500A further includes an interlayer dielectric layer 228 on the interlayer dielectric layer 224 and the conductive pattern 226. The interlayer dielectric layer 228 entirely covers the interlayer dielectric layer 224 and the conductive pattern 226. In some embodiments, the interlayer dielectric layers 224 and 228 may include the same or similar materials and processes. In some embodiments, the first protection pattern layer 212P and the second protection spacer 218R are formed of a first dielectric material, and the interlayer dielectric layers 224, 228 are formed of a second dielectric material that is different from the first dielectric material. For example, the first protection pattern layer 212P and the second protection spacer 218R may be formed of silicon oxide (SiO2), and the interlayer dielectric layers 224 and 228 may be formed of silicon nitride (SiN).

As shown in FIG. 1, the semiconductor device 500A further includes a source feature 230S and a drain feature 230D. The source feature 230S and the drain feature 230D are respectively disposed on the interlayer dielectric layer 228 and located on the opposite first side 220S1 and the second side 220S2 of the gate structure 220. The source feature 230S and the drain feature 230D respectively pass through the interlayer dielectric layers 224, 228 and the barrier layer 206. Moreover, the source feature 230S and the drain feature 230D respectively extend into portions of the channel layer 204 and are in contact with the channel layer 204. In some embodiments, the source feature 230S further passes the conductive pattern 226 and is in contact with and electrically connected to the conductive pattern 226. Moreover, the drain feature 230D and the conductive pattern 226 are separated from each other by the interlayer dielectric layer 228 along the direction 100.

In some embodiments, the source feature 230S and the drain feature 230D may include a single-layer or multi-layer structure formed of a conductive material such as a metal material. For example, the metal material may include gold (Au), nickel (Ni), platinum (Pt), palladium (Pd), iridium (Ir), titanium (Ti), chromium (Cr), tungsten (W), aluminum (Al), copper (Cu), titanium nitride (TiN) or a combination of thereof. In some embodiments, the conductive pattern 226 is formed of a first conductive material, and the source feature 230S and the drain feature 230D are formed of a second conductive material that is different from the first conductive material. For example, the conductive pattern 226 may be formed of titanium nitride (TiN), and the source feature 230S and the drain feature 230D may be formed of gold (Au) or copper (Cu).

FIG. 2 is a schematic cross-sectional view of a semiconductor device 500B in accordance with some embodiments of the disclosure, and the reference numbers the same or similar as those previously described with reference to FIG. 1 denote the same or similar elements. As shown in FIG. 2, the difference between the semiconductor device 500B and the semiconductor device 500A is that the semiconductor device 500B has a remaining portion 208PR of the gate layer 208P on the barrier layer 206 that is not covered by the first protection pattern layer 212P and the second protection spacer 218R, while the semiconductor device 500A does not have any remaining portions of the gate layer 208P on the barrier layer 206 that are not covered by the first protection pattern layer 212P and the second protection spacer 218R. In some embodiments, the remaining portion 208PR of the gate layer 208P includes an uneven thin film or island microstructures (an example of the remaining portion 208PR shown in FIG. 2 is an uneven thin film). In some embodiments, a thickness T3 of the remaining portion 208PR of the gate layer 208P is in a range of more than 0 nm to less than 15 nm, for example, 8 nm.

FIGS. 3 to 10 are schematic cross-sectional views of intermediate stages of forming the semiconductor device 500A of FIG. 1 in accordance with some embodiments of the disclosure. As shown in FIG. 3, a substrate 200 is provided. Next, several epitaxial growth processes are performed to sequentially form the buffer layer 202, the channel layer 204 and the barrier layer 206 on the top surface 200T of the substrate 200.

Please refer to FIG. 3 again, a gate material layer 208 and a gate electrode material layer 210 are then sequentially formed on the barrier layer 206. An epitaxial growth process may be performed to form the gate material layer 208 on the barrier layer 206. In some embodiments, the buffer layer 202, the channel layer 204, the barrier layer 206, and the gate material layer 208 may be in-situ deposited in the same deposition chamber. Next, a deposition process may be performed to form the gate electrode material layer 210 on the gate material layer 208.

Please refer to FIG. 3 again, next, a deposition process may be performed to form a first protection material layer 212 on the gate electrode material layer 210. In some embodiments, the first protection material layer 212 may include a dielectric material, such as silicon oxide (SiO2), silicon carbide, silicon nitride, silicon oxynitride, silicon carbonitride, silicon oxycarbide, silicon oxycarbonitride, tetraethoxysilane (TEOS) oxide, low dielectric constant dielectric material (the dielectric constant is less than 4), other suitable materials, or a combination thereof. In this embodiment, the first protection material layer 212 is a silicon oxide (SiO2) layer. In some embodiments, the thickness T1 of the first protection material layer 212 may be in a range of 1 nm to 100 nm, for example, 40 nm.

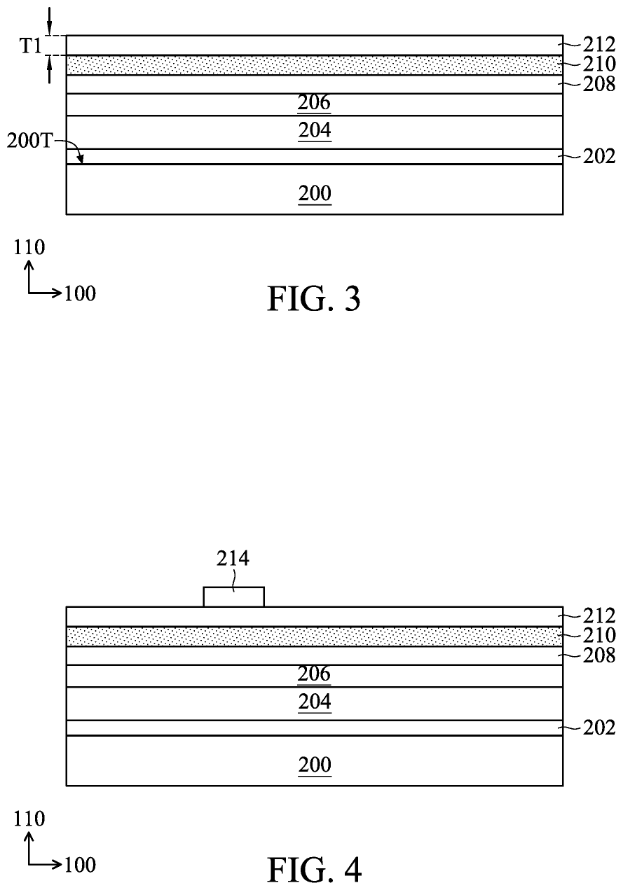

Next, as shown in FIGS. 4 to 6, a patterning process is performed to remove portions of the first protection material layer 212 and the gate electrode material layer 210 to form the first protection pattern layer 212P and the gate electrode layer 210P covered by the first protection pattern layer 212P. In some embodiments, the patterning process includes a lithography process followed by an etching process 300 (FIG. 5). Each step of the above-mentioned patterning process is described below with FIGS. 4 to 6.

As shown in FIG. 4, a mask pattern 214 partially covering the first protection material layer 212 is formed on the first protection material layer 212. In some embodiments, the mask pattern 214 such as a photoresist may be formed by a lithography process. In some other embodiments, the mask pattern 214 may be a hard mask, such as silicon oxide, silicon nitride, silicon oxynitride, silicon carbide, silicon carbon nitride, the like, or a combination thereof. In some embodiments, the mask pattern 214 may be formed by spin-on coating, physical vapor deposition (PVD), chemical vapor deposition (CVD), other suitable processes, or a combination of thereof.

Next, as shown in FIG. 5, an etching process 300 is performed to remove the first protection material layer 212 and the gate electrode material layer 210 not covered by the mask pattern 214 until the top surface 208T of the gate material layer 208 is exposed, so as to form the first protection pattern layer 212P and the gate electrode layer 210P. In some embodiments, the etch process 300 stops on the top surface 208T of the gate material layer 208 (no gate material layer 208 is removed), which may increase the uniformity of the subsequently formed gate layer 208P (FIG. 1) and prevent the gate layer 208P form damage. In some embodiments, the etching process 300 includes dry etching, wet etching, or a combination thereof. For example, the etching process 300 may include reactive ion etching (RIE), inductively-coupled plasma (ICP) etching, neutron beam etching (NBE), electron cyclotron resonance (ERC) etching, other suitable etching processes, or a combination of thereof. In some embodiments, the interface 208TC between the gate electrode layer 210P and the gate material layer 208 is coplanar with the top surface 208T of the gate material layer 208 after the patterning process.

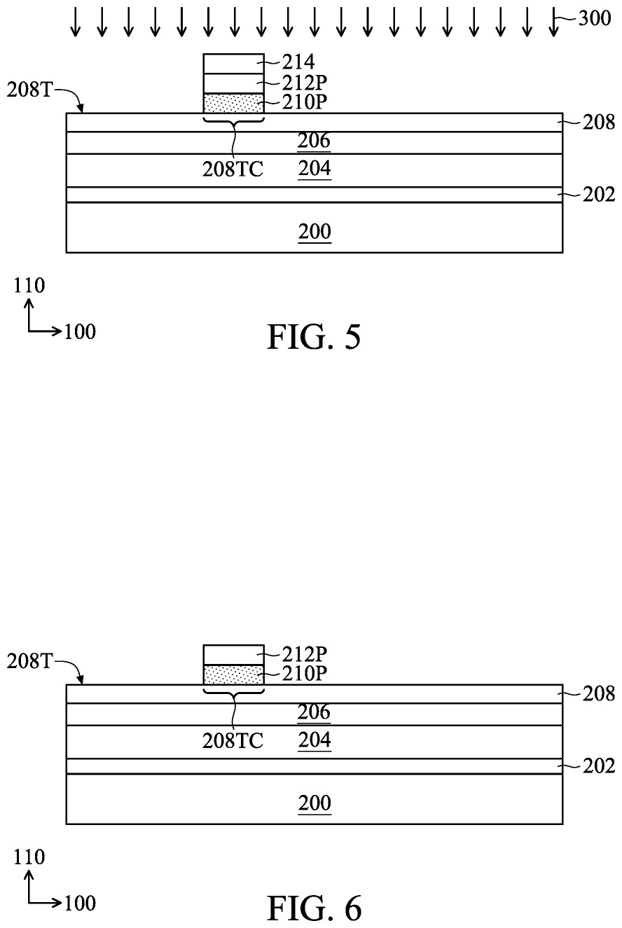

Next, as shown in FIG. 6, the mask pattern 214 is removed from the first protection pattern layer 212P. In some embodiments, the mask pattern 214 may be removed through a photoresist stripping process.

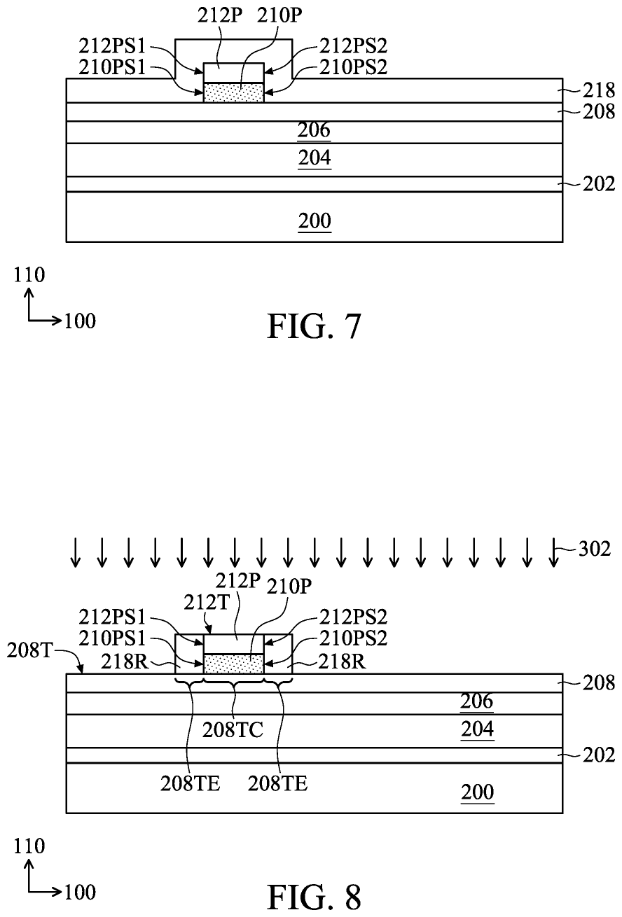

Next, as shown in FIG. 7, a deposition process may be performed to entirely form the second protection material layer 218. The second protection material layer 218 covers the top surface 212T and the opposite side surfaces 212PS1, 212PS2 of the first protection pattern layer 212P, the opposite side surfaces 210PS1, 210PS2 of the gate electrode layer 210P, and the gate material layer 208 not covered by the first protection pattern layer 212P and the gate electrode layer 210P.

Next, as shown in FIG. 8, an etching process 302 is performed to remove the second protection material layer 218 (FIG. 7) on the first protection pattern layer 212P and on the gate material layer 208 not covered by the first protection pattern layer 212P, until the top surface 212T of the first protection pattern layer 212P and the top surface 208T of the gate material layer 208 not covered by the first protection pattern layer 212P are exposed. Therefore, the second protection spacers 218R are formed covering the side surfaces 210PS1, 210PS2 of the gate electrode layer 210P and the side surfaces 212PS1, 212PS2 of the first protection pattern layer 212P in a self-aligned way. In some embodiments, the etching process 302 includes anisotropic etching, such as dry etching, including an etch-back process. In some embodiments, after the etching process 302, the interface 208TC between the gate electrode layer 210P and the gate material layer 208 and the interface 208TE between the second protection spacer 218R and the gate material layer 208 are coplanar.

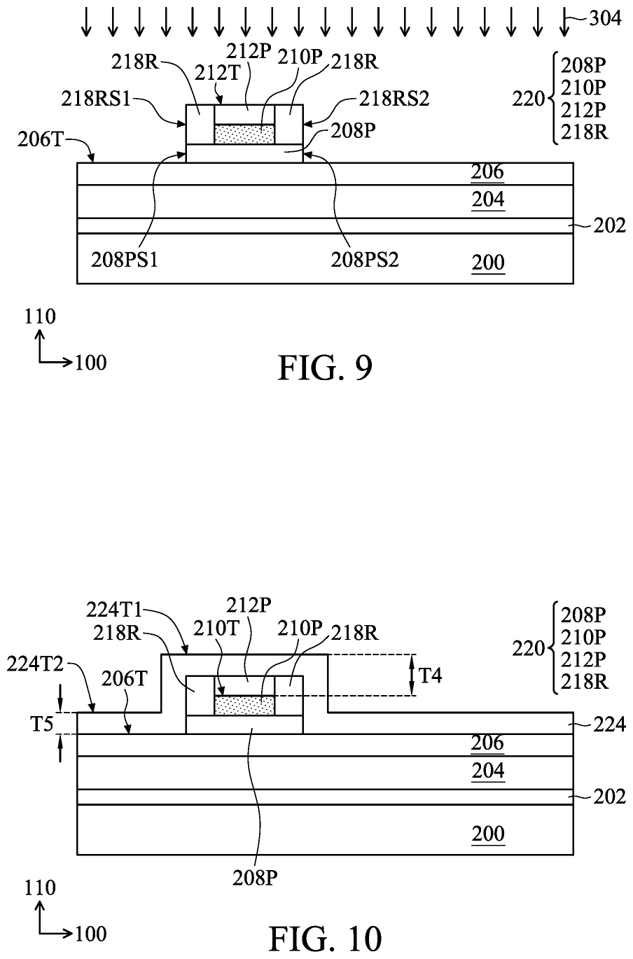

Next, as shown in FIG. 9, an etching process 304 is performed to completely remove the gate material layer 208 (FIG. 7) not covered by the first protection pattern layer 212P and the second protection spacers 218R using the first protection pattern layer 212P and the second protection spacer 218R as an etching mask, until the top surface 206T of the barrier layer 206 not covered by the first protection pattern layer 212P and the second protection spacer 218R is exposed. Therefore, the gate layer 208P is formed. After the etching process 304, outer side surfaces 218RS1, 218RS2 of the second protection spacer 218R are aligned with the corresponding side surfaces 208PS1, 208PS2 of the gate layer 208P. In addition, the opposite side surfaces 208PS1, 208PS2 of the gate layer 208P are completely exposed from the second protection spacer 218R. Furthermore, the gate layer 208P, the gate electrode layer 210P, the first protection pattern layer 212P and the second protection spacer 218R collectively form the gate structure 220. In some embodiments, the etching process 304 includes anisotropic etching, such as dry etching.

Next, as shown in FIG. 10, a deposition process may be performed to form the interlayer dielectric layer 224 directly on the first protection pattern layer 212P and the second protection spacer 218R. The interlayer dielectric layer 224 is entirely formed to completely cover the gate structure 220 and extend to the top surface 206T of the barrier layer 206. Also, the interlayer dielectric layer 224 is separated from the gate electrode layer 210P by the first protection pattern layer 212P and the second protection spacers 218R.

In some embodiments, there is a distance T4 between the top surface 210T of the gate electrode layer 210P and a top surface 224T1 of the interlayer dielectric layer 224 directly above the gate electrode layer 210P (that is, the total of the thickness of the first protection pattern layer 212P directly above the first top surface 210T of the gate electrode layer 210P and the thickness of the interlayer dielectric layer 224). Moreover, there is a distance T5 between the top surface 206T of the barrier layer 206 located on both side surfaces of the gate structure 220 and an upper surface 224T2 of the interlayer dielectric layer 224 directly above the barrier layer 206 on both side surfaces of the gate structure 220 (that is, the thickness of the interlayer dielectric layer 224 directly above the top surface 206T of the barrier layer 206 located on both side surfaces of the gate structure 220). In some embodiments, the distance T4 is greater than the distance T5, and the distance T5 is equal to the thickness of the interlayer dielectric layer 224.

Next, as shown in FIG. 1, a deposition process and a subsequent patterning process may be performed to form a conductive pattern 226 on a portion of the interlayer dielectric layer 224. The conductive pattern 226 completely covers the gate structure 220. Next, a deposition process may be performed to entirely form the interlayer dielectric layer 228. The interlayer dielectric layer 228 may completely cover the interlayer dielectric layer 224 and the conductive pattern 226.

Please refer to FIG. 1 again, next, a patterning process may be performed to form a source contact hole 230SC passing through the interlayer dielectric layer 228, the conductive pattern 226 and the interlayer dielectric layer 224 on the first side 220S1 of the gate structure 220. In addition, the patterning process may be performed to form a drain contact hole 230DC passing through the interlayer dielectric layer 228 and the interlayer dielectric layer 224 formed on the second side 220S2 of the gate structure 220. Moreover, the source contact hole 230SC and the drain contact hole 230DC respectively extend into portions of the channel layer 204.

Referring to FIG. 1 again, a deposition process may be performed to fill the source contact hole 230SC and the drain contact hole 230DC with a conductive material (not shown). Next, a patterning process may be performed to remove a portion of the conductive material on the interlayer dielectric layer 228, and form the source feature 230S and the drain feature 230D in the source contact hole 230SC and the drain contact hole 230DC respectively. The source feature 230S and the drain feature 230D both pass through the interlayer dielectric layers 228, 224 and the barrier layer 206 and are in contact with the channel layer 204. In addition, the source feature 230S may further pass through the conductive pattern 226. In some embodiments, the source feature 230S and the drain feature 230D are in ohmic contact with the channel layer 204. After the above processes, a semiconductor device 500A in accordance with some embodiments of the disclosure is formed.

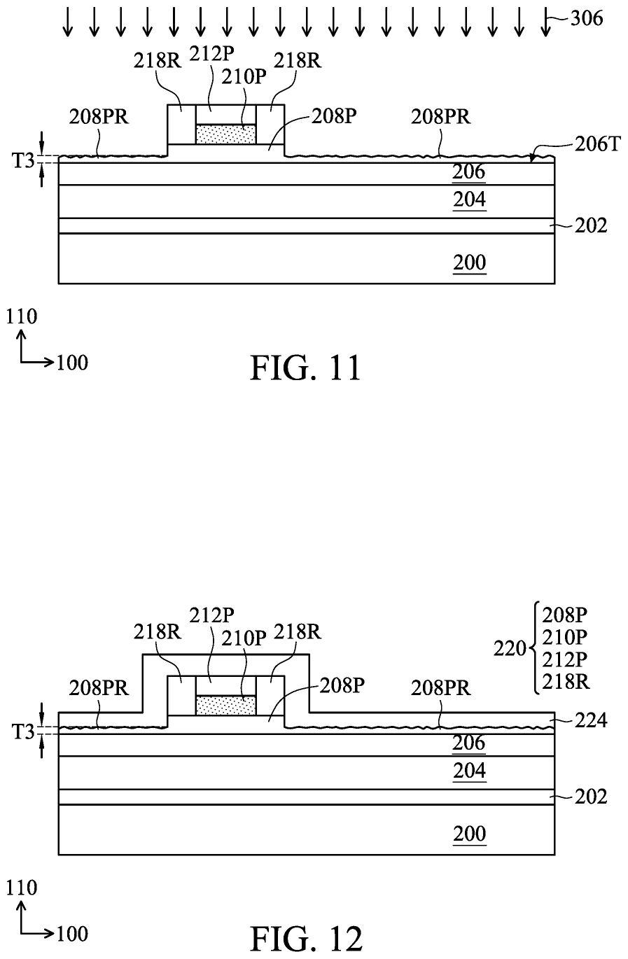

FIGS. 11 and 12 are schematic cross-sectional views of intermediate stages of forming the semiconductor device 500B of FIG. 2 in accordance with some embodiments of the disclosure, and the reference numbers the same or similar as those previously described with reference to FIGS. 3 to 10 denote the same or similar elements.

First, the processes the same or similar as those shown in FIGS. 3 to 8 are performed to form the gate electrode layer 210P, the first protection pattern layer 212P, and the second protection spacers 218R on the gate material layer 208 (FIG. 8). Next, as shown in FIG. 11, an etching process 306 is performed using the first protection pattern layer 212P and the second protection spacer 218R as an etching mask. In some embodiments, the etch process 306 partially removes the gate material layer 208 not covered by the first protection pattern layer 212P and the second protection spacers 218R (FIG. 8). Therefore, the gate layer 208P covered by the first protection pattern layer 212P and the second protection spacers 218R is formed, while the remaining portion 208PR of the gate material layer 208 (FIG. 8) remains on the barrier layer 206 not covered by the first protection pattern layer 212P and the second protection spacer 218R after the etching process 306. In some embodiments, the remaining portion 208PR has thickness TR along direction 110. In some embodiments, the thickness TR is in a range of greater than 0 nm and less than 15 nm, such as 8 nm. In some embodiments, the etching process 306 includes anisotropic etching, such as dry etching.

Next, as shown in FIG. 12, the process the same or similar as that shown in FIG. 10 is performed to entirely form the interlayer dielectric layer 224. The interlayer dielectric layer 224 completely covers the gate structure 220 and extends on the remaining portion 208PR (FIG. 11) of the gate material layer 208 (FIG. 8). In some embodiments, the surface of the remaining portion 208PR may not be an even surface, but an undulating surface. As shown in FIG. 12, the gate layer 208P, the gate electrode layer 210P, the first protection pattern layer 212P and the second protection spacer 218R collectively form a gate structure 220.

Then, as shown in FIG. 2, the subsequent deposition and patterning processes may be performed to form the conductive pattern 226 on a portion of the interlayer dielectric layer 224. Next, a deposition process may be performed to entirely form the interlayer dielectric layer 228.

Please refer to FIG. 2 again, next, a patterning process may be performed to form the source contact hole 230SC passing through the interlayer dielectric layer 228, the conductive pattern 226 and the interlayer dielectric layer 224 on the first side 220S1 of the gate structure 220. In addition, the patterning process may be performed to form a drain contact hole 230DC passing through the interlayer dielectric layer 228 and the interlayer dielectric layer 224 on the second side 220S2 of the gate structure 220.

Next, a deposition process and a subsequent patterning process may be performed to form the source feature 230S and the drain feature 230D in the source contact hole 230SC and the drain contact hole 230DC, respectively. After the aforementioned processes, the semiconductor device 500B in accordance with some embodiments of the disclosure is formed.

Embodiments provide a semiconductor device such as a high electron mobility transistor (HEMT) device and a method for forming the same. In some embodiments, before the first interlayer dielectric layer (the interlayer dielectric layer 224) is formed by a relatively high temperature deposition process (such as low pressure chemical vapor deposition (LPCVD)), the first protection pattern layer and the second protection spacers are formed on the gate electrode layer of the gate structure of the semiconductor device by a relatively low temperature deposition process (e.g., plasma enhanced chemical vapor deposition (PECVD)). In some embodiments, the first protection pattern layer and the second protection spacers, which are formed of, for example, silicon oxide, may completely surround the top surface and the side surfaces of the gate electrode before forming the first interlayer dielectric layer (the interlayer dielectric layer 224), which is formed of, for example, silicon nitride. In addition, the first protection pattern layer and the second protection spacers may separate the gate electrode layer from the first interlayer dielectric layer (the interlayer dielectric layer 224) thereon. Moreover, during the deposition processes for forming the first protection pattern layer and the second protection spacers, the surface of the gate electrode layer in contact with the first protection pattern layer and the second protection spacers is not easily affected by the deposition processes due to the lower process temperature. During the subsequent high-temperature deposition process for forming the first interlayer dielectric layer, the formation of the first protection pattern layer and the second protection spacers may maintain the interface state of the gate electrode layer and keep the surface of the gate electrode layer to be even. Further, the formation of the first protection pattern layer and the second protection spacers may prevent the gate electrode layer from being in contact with the first interlayer dielectric layer such as silicon nitride. Therefore, when the subsequent high temperature process is performed, the formation of the first protection pattern layer and the second protection spacers may prevent the gate electrode layer from cracking or peeling due to high stress occurring at the interface between the gate electrode layer and the first interlayer dielectric layer, and affecting the electrical properties and reliability of the resulting semiconductor device.

In addition, in some embodiments, the semiconductor device includes the conductive pattern as the field plate structure and the source and drain features in ohmic contact with the channel layer formed by different deposition processes and patterning processes. Moreover, the conductive pattern is formed before forming the second interlayer dielectric layer (the interlayer dielectric layer 228). The source feature and the drain feature are formed after the formation of the interlayer dielectric layer, and the source feature may vertically (along the direction 110) pass through the conductive pattern. Compared with conventional semiconductor devices that include a field plate structure and source/drain features connected to each other without any interface between them, and which are formed simultaneously using the same conductive material layer, the individually formed conductive pattern and the source and drain features of the present disclosure may prevent short-circuits. Short-circuits can be a problem in conventional semiconductor devices that are caused by the point discharge current (which comes from the tip of the conventional source/drain features) having a concentrated electric field that penetrates through the interlayer dielectric layer and reaches the gate electrode layer. Moreover, the conductive pattern (the field plate structure) and the source and drain features that are separately formed using different conductive material layers may improve the contact resistance (Rc) and process window of the source and drain features.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a buffer layer located on the substrate;
a channel layer located on the buffer layer;
a barrier layer located on the channel layer; and
a gate structure disposed on the barrier layer, wherein the gate structure comprises:
a gate layer;
a gate electrode layer partially covering the gate layer;
a first protection pattern layer completely covering a first top surface of the gate electrode layer; and
second protection spacers covering first side surfaces of the gate electrode layer, second side surfaces of the first protection pattern layer, and a portion of the gate layer not covered by the gate electrode layer, wherein first interfaces between the second protection spacers and the gate layer are coplanar with a second interface, which is between the gate electrode layer and the gate layer.

2. The semiconductor device as claimed in claim 1, wherein each of the first interfaces is a planar surface.

3. The semiconductor device as claimed in claim 1, wherein the first interfaces are adjacent to the second interface.

4. The semiconductor device as claimed in claim 1, wherein the gate layer has a second top surface, wherein the gate electrode layer and the second protection spacers are in contact with different portions of the second top surface.

5. The semiconductor device as claimed in claim 4, wherein the gate layer has third side surfaces, and the third side surfaces are connected to the second top surface and the barrier layer.

6. The semiconductor device as claimed in claim 5, wherein each of the third side surfaces is a planar surface extending from the second top surface to the barrier layer.

7. The semiconductor device as claimed in claim 5, wherein there is a remaining portion of the gate layer on the barrier layer not covered by the first protection pattern layer and the second protection spacers.

8. The semiconductor device as claimed in claim 7, wherein a thickness of the remaining portion of the gate layer is greater than 0 nm and less than 15 nm.

9. The semiconductor device as claimed in claim 1, wherein the first side surfaces of the gate electrode layer are aligned with the corresponding second side surfaces of the first protection pattern layer.

10. The semiconductor device as claimed in claim 1, further comprising:
a first interlayer dielectric layer disposed on the barrier layer and completely covering the gate structure;
a conductive pattern disposed on a portion of the first interlayer dielectric layer and completely covering the gate structure;
a second interlayer dielectric layer covering the first interlayer dielectric layer and the conductive pattern; and
a source feature and a drain feature disposed on the second interlayer dielectric layer and located on opposite sides of the gate structure, wherein the source feature and the drain feature respectively pass through the second interlayer dielectric layer, the first interlayer dielectric layer and the barrier layer and are in contact with the channel layer.

11. The semiconductor device as claimed in claim 10, wherein the source feature further passes through the conductive pattern, wherein the drain feature and the conductive pattern are separated from each other by the second interlayer dielectric layer.

12. The semiconductor device as claimed in claim 10, wherein the first protection pattern layer and the second protection spacers are formed of a first dielectric material, and the first interlayer dielectric layer is formed of a second dielectric material that is different from the first dielectric material.

13. A method for forming a semiconductor device, comprising:
providing a substrate;
sequentially forming a buffer layer, a channel layer and a barrier layer on the substrate;
sequentially forming a gate material layer and a gate electrode material layer on the barrier layer;
forming a first protection material layer on the gate electrode material layer;
performing a patterning process to remove a portion of the first protection material layer and a portion of the gate electrode material layer until a top surface of the gate material layer is exposed, so as to form a first protection pattern layer and a gate electrode layer covering a portion of the gate material layer;
entirely forming a second protection material layer;
removing the second protection material layer from the first protection pattern layer and from the gate material layer not covered by the first protection pattern layer, to form a second protection spacers covering the gate electrode layer and side surfaces of the first protection pattern layer;
performing an etching process to remove the gate material layer not covered by the first protection pattern layer and the second protection spacers to form a gate layer; and
directly forming a first interlayer dielectric layer on the first protection pattern layer and the second protection spacers.

14. The method for forming a semiconductor device as claimed in claim 13,
wherein an interface between the gate electrode layer and the gate material layer is coplanar with the top surface of the gate material layer after the patterning process.

15. The method for forming a semiconductor device as claimed in claim 13,
wherein the etching process completely removes the gate material layer not covered by the first protection pattern layer and the second protection spacers until the barrier layer not covered by the first protection pattern and the second protection spacers is exposed.

16. The method for forming a semiconductor device as claimed in claim 13,
wherein opposite side surfaces of the gate layer are completely exposed from the second protection spacers after the etching process.

17. The method for forming a semiconductor device as claimed in claim 13,
wherein a remaining portion of the gate material layer is form on the barrier layer not covered by the first protection pattern layer and the second protection spacers after the etching process.

18. The method for forming a semiconductor device as claimed in claim 13,
wherein the gate layer, the gate electrode layer, the first protection pattern layer and the second protection spacers form a gate structure, wherein after the first interlayer dielectric layer is formed, the method further comprises:
forming a conductive pattern on a portion of the first interlayer dielectric layer, wherein the conductive pattern completely covers the gate structure;
entirely forming a second interlayer dielectric layer; and
forming a source feature and a drain feature on the second interlayer dielectric layer on a first side and a second side of the gate structure, wherein the source feature and the drain feature respectively pass through the second interlayer dielectric layer, the first interlayer dielectric layer and the barrier layer and are in contact with the channel layer.

19. The method for forming a semiconductor device as claimed in claim 18,
wherein the source feature further passes through the conductive pattern.

20. The method for forming a semiconductor device as claimed in claim 18,
wherein forming the source feature and the drain feature comprises:
forming a source contact hole on the first side of the gate structure and passing through the second interlayer dielectric layer, the conductive pattern and the first interlayer dielectric layer;
forming a drain contact hole on the second side of the gate structure and passing through the second interlayer dielectric layer and the first interlayer dielectric layer; and
forming the source feature and the drain feature in the source contact hole and the drain contact hole, respectively.
